(19) United States
(12) Patent Application Publication
(10) Pub. No.: US 2013/0255751 A1
(43) Pub. Date: Oct. 3, 2013

(54) COMMON SOLAR-THERMAL ELECTRIC SYSTEM AND METHOD FOR ASSEMBLING

(71) Applicant: Charles Steven Korman, Niskayuna, NY (US)

(72) Inventor: Charles Steven Korman, Niskayuna, NY (US)

(73) Assignee: GENERAL ELECTRIC COMPANY, Schenectady, NY (US)

(21) Appl. No.: 13/435,858

(22) Filed: Mar. 30, 2012

(51) Int. Cl. H01L 31/058; F24J 2/34; H01L 31/18; F24J 2/24

(52) U.S. Cl. 136/248; 126/663; 126/640; 29/890.033

(57) ABSTRACT

A common solar-thermal electric system and a method for assembling the common solar-thermal electric system are provided. The common solar-thermal electric system includes an adjustable mounting rack. The adjustable mounting rack includes a plurality of rails that support at least one solar thermal module and at least one photovoltaic module. Further, the system includes an electric wiring connector with a plurality of connecting ports. The plurality of connecting ports are electrically coupled with electric jacks at each of the at least one photovoltaic module. Furthermore, the system includes a common piping assembly with a plurality of branching points. The plurality of branching points are mechanically coupled with output of each of the at least one solar thermal modules.

### BACKGROUND

The present invention relates, generally, to the field of solar energy utilization and more specifically to a common solar thermal electric system.

Energy demands in today's fast changing world cannot be satisfied through conventional fuels. Conventional fuels also pose the risk of causing pollution and thus risking the environment. These circumstances have led to an increase in the use of alternative sources of energy. Solar energy has been used for many years to satisfy energy demands of households.

Traditionally, energy from the sun has been used in the form of thermal energy. Thermal energy captured from the sun has been utilized to serve heating needs. Today, in residential environments, solar energy panels are installed on rooftops to capture incident solar energy and obtain thermal energy from it. The captured thermal energy is transferred to apparatuses that utilize thermal energy. For example, incident sunlight captured by solar panels is utilized, directly or indirectly, to heat water. Solar energy is also used to generate electric energy through the use of photovoltaic systems. In residential environments, like the solar-thermal panels, photovoltaic panels are installed on rooftops to capture incident solar energy. The incident energy is then converted to electric energy through the use of electronic circuitry.

To obtain maximum efficiency from these panels and systems, proper installation is important. Proper installation of solar-thermal panels and photovoltaic systems require large amount of fitting equipment and precise installation methods. Currently, in a large number of installation sites, solar thermal panels and photovoltaic systems are installed separately, occupying a large amount of space on rooftops. Further, both, solar-thermal as well as photovoltaic, systems utilize separate installation techniques, thereby adding to the installation costs of utilization of solar energy systems. Furthermore, heat energy dissipated by the photovoltaic systems that can be utilized by solar-thermal modules is lost due to the lack of integration between solar-thermal and photovoltaic systems.

In recent times, researchers have developed integrated solar-thermal and photovoltaic systems, that solve the problem of having multiple installations on the rooftop. However, customized installations that come along with such hybrid systems increase the total cost of utilizing solar energy for the energy needs of the household. The hybrid systems work on the principle of utilizing heat dissipated from the photovoltaic systems to perform the tasks of the solar-thermal panels. However, studies have shown that the thermal conversion efficiency of utilizing heat dissipated from the photovoltaic systems is much lesser than efficiency of dedicated solar-thermal panels. Owing to the reduced thermal conversion efficiency, more hybrid panels need to be fitted to satisfy thermal energy needs of an average household, adding further to the costs of utilizing solar energy.

Hence, there is a need for a common system to support solar-thermal as well as photovoltaic systems.

### BRIEF DESCRIPTION

Briefly in accordance with one aspect of the invention, a common solar thermal electric system is presented. The common solar thermal electric system includes an adjustable mounting rack. The adjustable mounting rack further includes a plurality of rails. The rails accommodate at least one solar thermal module and at least one photovoltaic module. Further, the common solar thermal electric system includes an electric wiring connector with a plurality of connecting ports. The plurality of connecting ports are electrically coupled with electric jacks at each of the at least one photovoltaic module. Furthermore, the common solar thermal electric system includes a common piping assembly with a plurality of branching points. The plurality of branching points are mechanically coupled with output of each of the at least one solar thermal modules.

In accordance with a further aspect of the present invention, a method for assembling a common solar thermal electric system is presented. The method includes the step of inserting at least one solar thermal module and at least one photovoltaic module in at least one of a plurality of rails in an adjustable mounting rack. Further, the method includes the step of connecting an electric jack on the at least one photovoltaic module to an electric wiring connector. Furthermore, the method includes the step of coupling an output of the at least one solar thermal module to at least one of a plurality of branching points in a common piping assembly.

### DRAWINGS

These and other features, aspects, and advantages of the present invention will become better understood when the following detailed description is read with reference to the accompanying drawings in which like characters represent like parts throughout the drawings, wherein:

FIG. 1 is a front view of a common solar-thermal electric system, in accordance with certain embodiments of the present invention;

FIG. 2 is a view of a disassembled common solar-thermal electric system, in accordance with aspects of the present invention;

FIG. 3 is a perspective view of electrical and plumbing connections on the common solar-thermal electric system, in accordance with certain embodiments of the present invention; and

FIG. 4 is a flow chart illustrating a method for assembling the common solar-thermal electric system, in accordance with an embodiment of the present invention.

### DETAILED DESCRIPTION

Reference will be made below in detail to exemplary embodiments of the invention, examples of which are illustrated in the accompanying drawings. Wherever possible, the same reference numerals used throughout the drawings refer to the same or like parts.

Embodiments of the invention described herein relate to a common solar-thermal electric system that provides for energy needs of a site at which the system is installed. The solar-thermal electric system converts radiant solar energy to thermal as well as electric energy and provides it to a plurality of output points in the installation site. The system includes an adjustable mounting rack with a plurality of rails. The plurality of rails are designed to support at least one solar-thermal module and at least one photovoltaic module. The system also has an electric wiring connector and a common piping assembly. The electric wiring connector has a plurality of electric connecting ports that are electrically coupled to the photovoltaic modules supported by the adjustable mounting rack. Further, the common piping assembly has a plurality of branching points that are mechanically coupled to output of the at least one solar-thermal module. The photovoltaic modules convert solar energy to electric energy. The available electric energy is received from each photovoltaic module in the common solar-thermal electric system by the electric wiring connector. The electric wiring connector runs across the length of the common solar-thermal electric system to allow electric jacks of each of the photovoltaic modules to be coupled with the electric connecting ports. The common piping assemby also runs across the length of the common solar-thermal electric system to allow outputs of each of the solar-thermal modules to be coupled with branching points located on the common piping assembly.

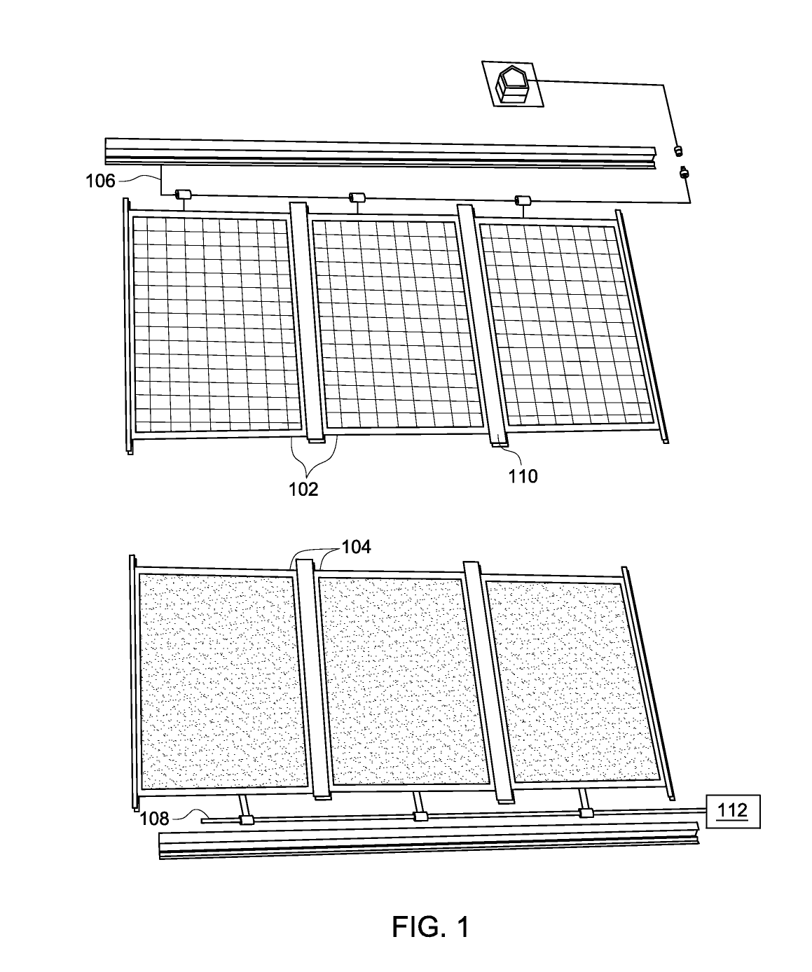

Turning now to the drawings, and referring to FIG. 1, a front view of a common solar-thermal electric system 100, in accordance with aspects of the present invention, is depicted. The common solar-thermal electric system 100 is typically installed on a mounting surface like roof tops of sites like residential and commercial buildings to utilize solar energy. The common solar-thermal electric system 100 includes at least one photovoltaic module 102, at least one solar-thermal module 104, an electric wiring connector 106, a common piping assembly 108, an adjustable mounting rack 110, and a plumbing junction box 112. The at least one photovoltaic module 102 and the at least one solar-thermal module 104 are supported by a plurality of rails in the adjustable mounting rack 110. Further, the electric wiring connector 106, which includes a plurality of connecting ports, is electrically coupled with electric jacks of each of the at least one photovoltaic module 102. Furthermore, output of each of the at least one solar-thermal module 104 and the common piping assembly 108 are mechanically coupled at a plurality of branching points located on the common piping assembly 108.

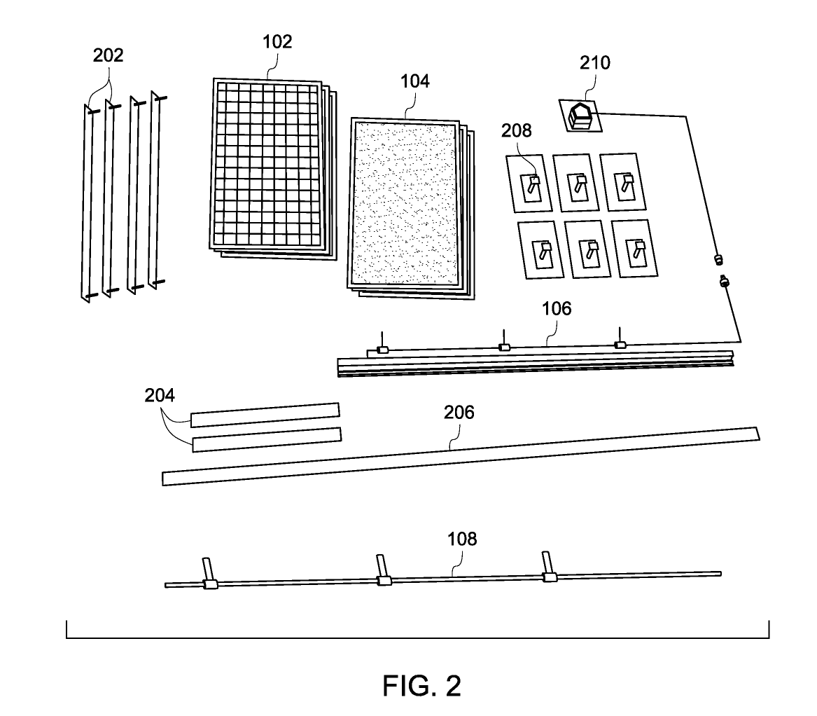

According to one embodiment of the present invention, the rails in the adjustable mounting rack 110 include an insert slot and a capture slot. The insert slot 210 supports one edge of the photovoltaic module 102 and the solar-thermal module 104. The insert slot of the plurality of rails is configured to receive one edge of the modules 102 and 104. Accordingly, in one embodiment, the insert slot defines an angular “C” shape to hold the edge of the modules 102 and 104 that is inserted during installation. An opposite edge of the modules 102 and 104 is supported by the capture slot of the rails in the adjustable mounting rack 110. The capture slot, according to certain embodiments, includes a ledge-like boundary to support an edge of the modules 102 and 104. Further, the edge of the modules 102 and 104 is clamped to the ledge-like boundary of the capture slot using a clamp slot. The clamp slot provides for space to accommodate a clamp used to hold an edge of the modules 102 and 104. According to certain embodiments, the clamp slot is a substantively horizontal platform on to which the clamp may be attached. In the illustrated embodiment of FIG. 1, the rails of the adjustable mounting rack 110 are placed vertically i.e. in a direction parallel to the length of the modules 102 and 104. In this configuration, to support three modules 102, four rails are used. In another configuration, the plurality of rails can be place horizontally in a direction perpendicular to the length of the modules 102 and 104, in such a way that the insert slot of one of the plurality of rails can hold one edge of multiple modules 102 and 104 and capture slot of one of the plurality of rails can hold another edge of the multiple modules 102 and 104. In this configuration, multiple modules 102 and 104 are placed adjacent to each other. Further, as illustrated in FIG. 2, end caps 202 are used to seal the modules 102 and 104 on the edges that are not supported either by the insert slot, capture slot, or another module. According to certain embodiments, the mounting apparatus as described in commonly assigned patent application US20110209745 can be used as the adjustable mounting rack 110.

According to certain embodiments, the plurality of connecting ports of the electric wiring connector 106 are electrically coupled with the electric jacks of the at least one photovoltaic module 102 by inserting one end of an electrically conductive wire in the electric jack of the module 102 and another end of the electrically conductive wire in one of the plurality of connecting ports. According to another embodiment, the electric jacks on the at least one photovoltaic module 102 are male connectors and the plurality of connecting ports are female connectors. The electric jack has a plurality of wires that electrically couple the electric jack to the at least one photovoltaic module. The electric jack is connected at one end with electronic circuitry of the at least one photovoltaic module 102 and has at least one wire on another end that is grounded and at least one wire that provides electric energy to the plurality of connecting ports. The electronic circuitry for conversion of solar energy incident on the photovoltaic module 102 to electric energy includes, but is not limited to, power converters, charge controllers and the like. The electronic circuitry is fitted on a side of the photovoltaic module 102 that is not capturing the incident solar energy. According to the embodiment shown in FIG. 1, the electric wiring connector 106 is placed on top of the photovoltaic modules 102. In other embodiments, the electric wiring connector 106 is placed below the photovoltaic modules 102.

To utilize thermal energy generated at the solar-thermal module 104, input pipes carrying liquid that needs to be heated are provided. The input pipes are connected in a way that they draw thermal energy from the solar-thermal module 104 and thus heat the liquid they carry. The input pipes flow across the length and breadth of the solar-thermal module 104. According to one embodiment, the input pipes are installed in a zigzag fashion below the solar-thermal module 104. The heated liquid is passed out of the solar-thermal module 104 through an output of the solar thermal module 104. The branching points of the common piping assembly 108 are mechanically coupled with the at least one solar-thermal module 104 at the output of each of the at least one solar-thermal modules 104. The branching points and the output of the solar-thermal modules 104, according to one embodiment, are mechanically coupled with the help of flexible pipes. According to another embodiment, the branching points and the output of the solar-thermal modules 104 are mechanically coupled using rigid pipes. The branching points, according to certain embodiments, are female threaded elbows that are connected to a female threaded output of the solar-thermal modules 104 with the help of a male threaded pipe. Various plumbing connectors like couplings, tee junctions, reducers and the like can be used as branching points. The pipes connecting the branching points with the outputs of the solar-thermal modules 104 can be fitted by simply inserting one end of the pipe in one of the branching points and the other end in the output of the solar-thermal module 104. Further, other techniques including, but not limited to, soldering, welding, fastening, and brazing can be used to connect the pipe with the branching points and the outputs of the solar-thermal modules 104. Further, the common piping assembly is mechanically coupled with the plumbing junction box 112. The plumbing junction box 112 is connected to all the plumbing connections at the installation site that will utilize the heated liquid. In certain other embodiments, the common piping assembly 108 is also mechanically coupled with a storage reservoir to store the heated liquid that the solar-thermal module 104 outputs. The storage reservoir includes, but is not limited to, tanks on the rooftop of the environment, sumps in the basement of the environment, and the like. The electric wiring connector 106 and the common piping assembly 108 are placed substantially away from each other to avoid electric wires from the electric wiring connector 106 from coming in contact with the liquid carried by the common piping assembly 108.

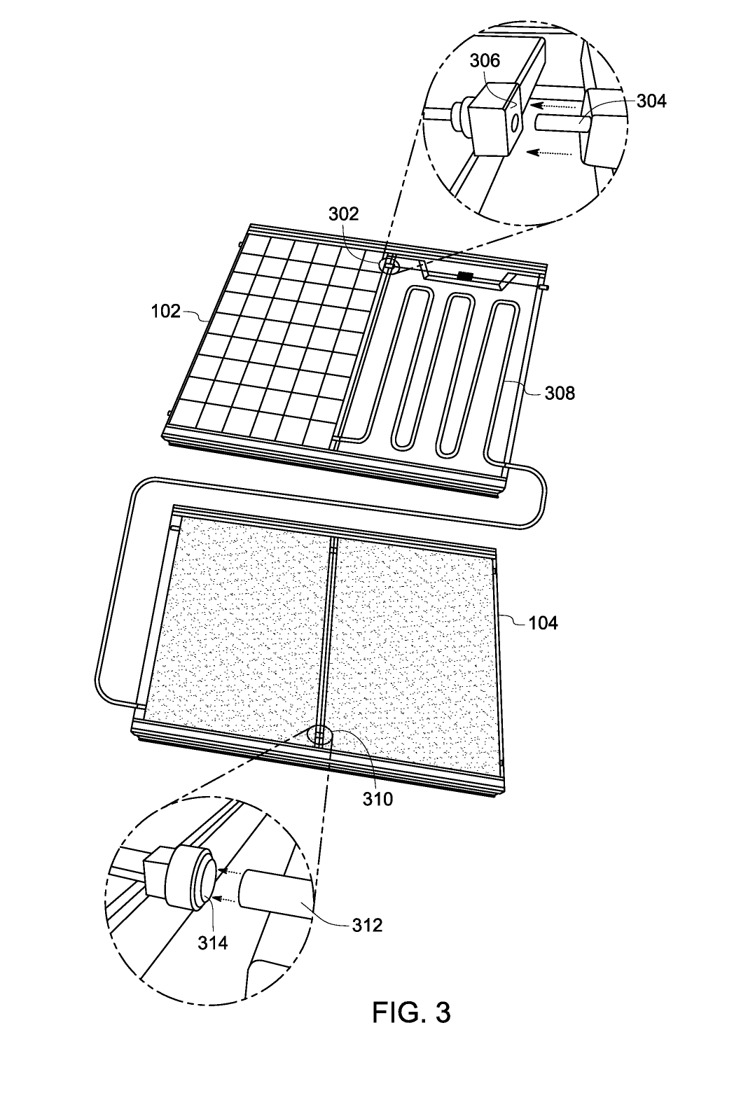

According to one embodiment, in the common solar-thermal electric system 100, the input pipe carrying liquid to be heated towards the solar-thermal module 104 is placed proximate to the at least one photovoltaic module 102. The input pipe, due to its proximity to the at least one photovoltaic module 102, draws heat dissipated by the at least one photovoltaic module 102 while converting solar energy to electric energy. As illustrated in FIG. 3, input pipe 308 of the solar-thermal module 104 is placed on a side of the photovoltaic module 102 that is not capturing the incident solar energy.

FIG. 2 is a view of a disassembled common solar-thermal electric system 100, in accordance with aspects of the present invention. The common solar-thermal electric system 100, as explained in conjunction with FIG. 1, includes at least one photovoltaic module 102, at least one solar-thermal module 104, electric wiring connector 106, common piping assembly 108. Further, in order to install the common solar-thermal electric system 100 on the mounting surface, module end caps 202, module locking covers 204, a front edge finish trim 206, a plurality of stanchions 208 are required. The module end caps 202 are placed at one end of the module placed on either ends of the common solar-thermal electric system. For example, in FIG. 1, the module end caps 202 are placed to hold the photovoltaic modules 102 placed at each end of the top row, and to hold the solar-thermal modules 104 placed at each end of the bottom row. The module locking covers 204 are placed on each of the at least one photovoltaic module 102 and the solar thermal module 104 on a side that is not supported by the plurality of rails of the adjustable mounting rack 110. Further, frames of each of the modules 102 and 104 are placed on the plurality of stanchions 208. The plurality of stanchions 208 are fixed to the mounting surface and hold the adjustable mounting rack 110 on one end.

Also included in the common solar-thermal electric system 100 is an electric junction box 210. The electric junction box 210 is connected to the electric wiring connector 106. The electric wiring connector 106 provides electric energy from the photovoltaic modules 102 to the electric junction box 210. The electric junction box is connected to at least one socket consuming electric energy in the environment where the common solar-thermal electric system 100 is installed.

FIG. 3 is a perspective view of electrical and plumbing connections on the common solar-thermal electric system, in accordance with certain embodiments of the present invention. In the aforementioned series configuration of modules 102 and 104, where multiple modules 102 and 104 are inserted in two different rows in the plurality of rails of the adjustable mounting rack 110. According to one embodiment, the modules 102 and the modules 104 are connected to each other in series. In order to connect all the modules 102, electric jacks on each of the module 102 are utilized. In the illustrated embodiment of FIG. 3, modules 102 are linked by a connection 302. In the detailed illustration of connection 302, the electric jacks of each module 102 that includes a male connector 304 and a female connector 306 are connected to adjacent modules 102. The male connector 304 of one of the modules 102 is inserted in the female connector 306 of another adjacent module 102. Further, one of the male or female connectors 304 and 306 in the electric jack of the module 102 that does not have any module 102 adjacent to it is electrically coupled with one of the plurality of connecting ports of the electric wiring connector 106. The electric wiring connector 106 is further connected to the electric junction box 210.

Similarly, input and output of each module 104 is linked to each other by a connection 310. At the connection 310, input of one of the modules 104—a male connecting pipe 312 and output of another adjacent module 104—a female connecting bore 314, are linked. The male connecting pipe 312 of one of the modules 104 is inserted into the female connecting bore 314 of another adjacent module 104. In one embodiment, the output of the module 104 that is not connected to the input of adjacent module 104 is mechanically coupled with at least one of the branching points of the common piping assembly 108.

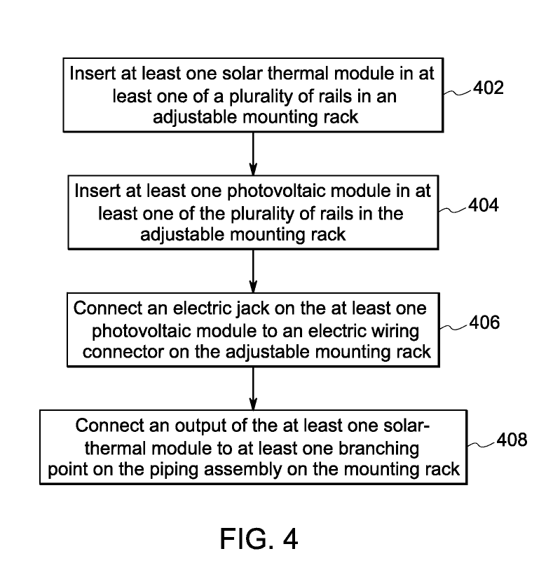

FIG. 4 is a flow chart illustrating a method for assembling the common solar-thermal electric system 100, in accordance with an embodiment of the present invention. At step 402, at least one solar-thermal module 104 is inserted in at least one of the plurality of rails of the adjustable mounting rack 110. As described in conjunction with FIG. 1, the rails of the adjustable mounting rack 110 includes insert slot and capture slot. For assembling the common solar-thermal electric system 100 in accordance with the configuration illustrated in FIG. 1, the plurality of rails are assembled vertically, where the insert slot of one of the plurality of rails is facing the capture slot of another of the plurality of rails. One edge of the solar-thermal module 104 is inserted in the insert slot of one of the plurality of rails. The other edge of the solar-thermal module 104 is placed on the capture slot and clamped to the capture slot with the help of the clamp slot. Further, at step 404, at least one photovoltaic module 102 is inserted in one of the plurality of rails of the adjustable mounting rack 110. As discussed earlier, one edge of the photovoltaic module 102 is inserted in the insert slot of the rail and another edge of the photovoltaic module 102 is placed and clamped to the capture slot of the rail. Multiple modules 102 and 104 are inserted similarly to form an array each of solar-thermal modules 104 and photovoltaic modules 102. The modules 102 and 104 are placed on the adjustable mounting rack 110 in a direction substantially parallel to the mounting surface. In certain embodiments, the modules 102 and 104 are placed in an inclined position with respect to the mounting surface.

According to one embodiment, the adjustable mounting rack 110 is mechanically coupled with a plurality of stanchions located on the mounting surface. The stanchions hold the adjustable mounting rack 110 in a fixed position to maintain the substantially parallel alignment of the modules 102 and 104 with the mounting surface.

Further, at step 406, the electric jack of the photovoltaic module 102 is electrically coupled with at least one of the plurality of connecting ports on the electric wiring connector 106. The electric wiring connector 106 is mechanically coupled with the adjustable mounting rack 110 to hold the electric wiring connector 106 in a fixed position. At step 408, the output of the at least one solar-thermal module 104 is mechanically coupled with at least one of the plurality of branching points of the common piping assembly 108. The output of the solar-thermal module 104 and the branching points are coupled with the help of pipes that are fitted, on one end, to the output of the module 104, and on another end, to one of the branching points.

According to one embodiment, the method also includes the step of electrically coupling the electric wiring connector 106 to the electric junction box 210. The electric junction box 210 is further electrically coupled with at least one socket that utilizes the electric energy provided by the at least one photovoltaic module 102. Further, the method also includes the step of mechanically coupling the common piping assembly 108 with a storage reservoir to store the heated liquid that the solar-thermal module 104 outputs. The storage reservoir includes, but is not limited to, tanks on the rooftop of the environment, sumps in the basement of the environment, and the like.

According to certain embodiments, a series configuration of modules 102 and 104 is provided. To provide the series configuration, in the method of assembly, the plurality of rails are placed horizontally, where the insert slot and capture slot of the plurality of rails are placed in a direction perpendicular to the length of the modules 102 and 104. One set of rails is configured to hold the modules 102 serially and another set of rails is configured to hold the modules 104 serially. One edge of each of the multiple modules 102 is inserted serially in the insert slot of one of the rails and another edge of each of the multiple modules 102 is placed on the capture slot of another rail of the plurality of rails. The modules 102 are thus placed in such a way that they are adjacent to each other. The modules 102, according to one embodiment, are electrically coupled to each other by way of the connection 302 described in FIG. 3. Similarly, for modules 104 that are placed in a serial order, connection 310 from FIG. 3 is utilized to connect the modules 104 with one another. Alternatively, the modules in serial fashion are not physically coupled but are placed adjacent to each other without any interconnections. Further, in the serial configuration, a common electric output from one of the electric jacks of the series of modules 102 is connected to the electric wiring connector 106 and a common output of the solar-thermal modules 104 is connected to the common piping assembly 108.

The method of assembling the common solar-thermal electric system 100 also includes the step of placing the input pipe 308 of the solar-thermal module 104 proximate to the photovoltaic modules 102. The input pipe 308 when placed proximate to the photovoltaic modules 102 utilize the heat dissipated from the photovoltaic modules 102 and provide pre-heated liquid as input to the solar-thermal modules 104. Input pipes are placed proximate to the photovoltaic modules 102 to increase efficiency of the solar-thermal modules 104 and reduce the time taken to provide heated liquid to the environment.

Various embodiments of an exemplary common solar-thermal electric system and method for assembling the common solar-thermal electric system substantially reduce the manufacturing cost and cost of installing solar energy utilization systems. Further, the common solar-thermal electric system can be installed easily and thus reduces the time interval between acquiring solar energy utilization systems and utilizing solar energy utilization systems.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. While the dimensions and types of materials described herein are intended to define the parameters of the invention, they are by no means limiting and are exemplary embodiments. Many other embodiments will be apparent to those of ordinary skill in the art upon reviewing the above description. The scope of the invention should, therefore, be determined with reference to the appended claims, along with the full scope of equivalents to which such claims are entitled. In the appended description, the terms “including” and “in which” are used as the plain-English equivalents of the respective terms “comprising” and “wherein.” Moreover, in the following claims, the terms “first,” “second,” etc. if any, are used merely as labels, and are not intended to impose numerical or positional requirements on their objects. Further, the limitations of the following claims are not written in means-plus-function format and are not intended to be interpreted based on 35 U.S.C. §112, sixth paragraph, unless and until such claim limitations expressly use the phrase “means for” followed by a statement of function void of further structure.

This written description uses examples to disclose several embodiments of the invention, including the best mode, and also to enable any person of ordinary skill in the art to practice the embodiments of invention, including making and using any devices or systems and performing any incorporated methods. The patentable scope of the invention is defined by the claims, and may include other examples that occur to those of ordinary skill in the art. Such other examples are intended to be within the scope of the claims if they have structural elements that do not differ from the literal language of the claims, or if they include equivalent structural elements with insubstantial differences from the literal languages of the claims.

As used herein, an element or step recited in the singular and proceeded with the word “a” or “an” should be understood as not excluding plural of said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising,” “including,” or “having” an element or a plurality of elements having a particular property may include additional such elements not having that property.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A common solar thermal electric system, comprising:
an adjustable mounting rack comprising a plurality of rails, wherein the plurality of rails support at least one solar thermal module and at least one photovoltaic module;
an electric wiring connector with a plurality of connecting ports, wherein the plurality of connecting ports are electrically coupled with electric jacks at each of the at least one photovoltaic module; and
a common piping assembly with a plurality of branching points, wherein the plurality of branching points are mechanically coupled with output of each of the at least one solar thermal modules.

2. The common solar thermal electric system of claim 1 further comprises a plurality of stanchions to dispose the adjustable mounting rack on a mounting surface.

3. The common solar thermal electric system of claim 1, wherein the plurality of rails comprise an insert slot and a capture slot to support the at least one solar thermal module and the at least one photovoltaic module.

4. The common solar thermal electric system of claim 3, wherein the insert slot is a C shaped slot to allow for insertion of at least one edge of the at least one solar-thermal module and the at least one photovoltaic module.

5. The common solar thermal electric system of claim 3 further comprises a clamp slot to fix to the capture slot at least one edge of the at least one solar-thermal module and the at least one photovoltaic module.

6. The common solar thermal electric system of claim 1, further comprises pipes made of flexible material to mechanically couple the output of each of the at least one solar thermal modules with the common piping assembly through the plurality of branching points.

7. The common solar thermal electric system of claim 1 further comprises at least one input pipe of the at least one solar thermal module, wherein the at least one input pipe is located proximate to the at least one photovoltaic module.

8. The common solar thermal electric system of claim 1, wherein the electric jacks are mechanically coupled to the electric wiring connector by insertion of the electric jacks in the plurality of connecting ports.

9. The common solar thermal electric system of claim 1 further comprises an electric junction box, wherein the electric junction box receives electric input from the electric wiring connector and provides electric output to at least one electric socket that utilizes electricity.

10. The common solar thermal electric system of claim 1 further comprises a storage reservoir, wherein the common piping assembly is mechanically coupled with the storage reservoir.

11. The common solar thermal electric system of claim 1, wherein the electric jack of the at least one photovoltaic module is coupled to an adjacent electric jack of the at least one adjacent photovoltaic module.

12. A method for assembling a common solar thermal electric system, the method comprising:
inserting at least one solar thermal module in at least one of a plurality of rails in an adjustable mounting rack;
inserting at least one photovoltaic module in at least one of the plurality of rails in the adjustable mounting rack;
connecting an electric jack on the at least one photovoltaic module to an electric wiring connector, wherein the electric wiring connector is mechanically coupled with the adjustable mounting rack; and
coupling an output of the at least one solar thermal module to at least one of a plurality of branching points in a common piping assembly, wherein the common piping assembly is mechanically coupled with the adjustable mounting rack.

13. The method of claim 12 further comprises connecting the electric wiring connector to a junction box, wherein the junction box is connected to at least one electric socket that utilizes electricity.

14. The method of claim 12 further comprises mechanically coupling the common piping assembly to a storage reservoir.

15. The method of claim 12 further comprises mechanically coupling the adjustable mounting rack with a stanchion, to dispose the solar-thermal and the photovoltaic module on a mounting surface.

16. The method of claim 15 further comprises aligning the adjustable mounting rack in a position substantially parallel to the mounting surface.

17. The method of claim 12 further comprises disposing an input pipe of the at least one solar thermal module proximate to the photovoltaic module.

18. The method of claim 12 further comprises inserting the electric jack of the at least one photovoltaic module in an adjacent electric jack of an adjacent photovoltaic module.
